(19) United States
(12) Patent Application Publication
(10) Pub. No.: US 2025/0369580 A1
(43) Pub. Date: Dec. 4, 2025

(54) SOLAR PANEL ARRAY

(71) Applicant: Gama Sonic USA, Inc., Norcross, GA (US)

(72) Inventor: Lazar Izradel, Tel Aviv (IL)

(73) Assignee: Gama Sonic USA, Inc., Norcross, GA (US)

(21) Appl. No.: 19/306,041

(22) Filed: Aug. 21, 2025

Related U.S. Application Data
(63) Continuation of application No. 17/147,672, filed on Jan. 13, 2021.

(51) Int. Cl. F21S 9/03; F21S 8/08; F21V 15/01; F21W 131/10; F24S 20/00; H02J 7/35; H02S 20/10; H02S 40/36; H10F 19/00; H10F 19/20; H10F 19/90; H10F 77/00

(52) U.S. Cl. CPC F21S 9/037; H02J 7/35; H02S 20/10; H02S 40/36; H10F 19/00; H10F 19/20; H10F 19/902; H10F 77/00; H10F 77/939; F21S 8/088; F21V 15/01; F21W 2131/10; F24S 2020/18; Y02B 20/72; Y02E 10/50

(57) ABSTRACT

A solar energy device includes a solar panel array including a plurality of solar panels, each of the solar panels being divided into solar sub-panels. The solar sub-panels have unequal shapes but equal areas. Wires electrically connect the solar sub-panels and connect the solar panels. The solar panels are secured on a base which is formed with cutouts to receive the wires. The wires are fixed to the solar sub-panels but are free to move with respect to the base.

### CROSS-REFERENCE TO PRIOR APPLICATIONS

This application claims priority from and is a continuation of U.S. patent application Ser. No. 17/147,672, filed 13 Jan. 2021, which claims priority from and is a continuation of, U.S. patent application Ser. No. 15/622,316, filed Jun. 14, 2017, which is a continuation-in-part of U.S. patent application Ser. No. 14/976,113, filed Dec. 21, 2015, now abandoned, which are incorporated herein by reference.

### FIELD OF THE INVENTION

The present invention relates generally to solar lighting and particularly to an array of unequally shaped solar panels and a light fixture therefor.

### BACKGROUND OF THE INVENTION

Various exterior lighting systems use photovoltaic panels (solar panels) powered by batteries. Sunlight impinges on the solar panel and charges the battery or batteries during the day time. The battery can subsequently provide a source of electricity for a lighting element during the nighttime. The battery is usually mounted in or about a fixed vertical pole.

A known problem that can occur with solar panels that degrades their lifetime is hot spots on the panel. Hot spots may damage the photovoltaic cell by overheating and may also lead to melting of solder joints, or creation of pin holes or open circuits in the cell. Hot spots may develop due to some cells being exposed to more or less sunlight than other cells, due to partial shading, dirt or bird droppings in a localized area, temperature variations across a panel, and non-uniform aging of the diffusion regions from cell to cell.

The destructive effects of hot-spot heating may be circumvented with a bypass diode. The bypass diode is connected in parallel, but with opposite polarity, to the solar cell. Under normal operation, each solar cell is forward biased and therefore the bypass diode is reverse biased and acts as an open circuit. However, if the solar cell is reverse biased due to a mismatch in short-circuit current between several series connected cells, then the bypass diode conducts, thereby allowing the current from the good solar cells to flow in the external circuit rather than forward biasing each good cell, thus limiting the current and preventing hot-spot heating.

### SUMMARY OF THE INVENTION

The present invention seeks to provide an array of unequally shaped solar panels, as is described more in detail hereinbelow. In the present invention, although the solar panels have unequal shapes, the areas of all solar panels connected in series are equal. Every cell outputs equal power. This avoids unequal current flow through the panels and helps prevent hot spots. A light fixture is also provided which is powered by the electricity generated by the solar panels.

The present invention enables making an efficient solar panel in any shape, such as but not limited to, curved, concave, any other geometric shape.

One of the advantages of the invention is maximization of the solar panel power for a given surface/area, which is not necessarily square, by using different solar panels with unequal shapes but equal areas. The invention can be used to create solar powered lights without a need for a remote solar panel; the solar panel is sufficient to operate the light. The invention enables developing products that follow the market trend in terms of design, and yet still provide a maximum area solar panel that uses most of the available surface on the light fixture.

There is provided in accordance with an embodiment of the invention a solar energy device including a solar panel array including a plurality of solar panels, each of the solar panels being divided into solar sub-panels, wherein the solar sub-panels have unequal shapes but equal areas, wires electrically connecting the solar sub-panels and connecting the solar panels, and a base on which the solar panels are secured, the base being formed with cutouts to receive the wires. The wires are fixed to the solar sub-panels but are free to move with respect to the base.

In accordance with an embodiment of the invention the base has a curved outer contour.

In accordance with an embodiment of the invention the base has a concave cone shape.

In accordance with an embodiment of the invention the base includes a plurality of sub-bases around its periphery for mounting thereon on the solar panels.

In accordance with an embodiment of the invention the cutouts include a trough formed in each of the sub-bases that extends at least partially from a lower portion of the base to a top portion of the base and one or more apertures formed in each of the sub-bases.

In accordance with an embodiment of the invention a top portion of the base includes a cap or connector.

In accordance with an embodiment of the invention a transparent protective cover is assembled over the solar panels. A gap between the solar panels and an inner periphery of the protective cover may be filled with a transparent filler material. A light fixture may be assembled with the solar panel array. The light fixture may include one or more lights powered by energy generated by the solar panel array.

### BRIEF DESCRIPTION OF THE DRAWINGS

The present invention will be understood and appreciated more fully from the following detailed description, taken in conjunction with the drawing in which:

FIG. 1 is a simplified pictorial illustration of a base for a solar panel array, constructed and operative in accordance with an embodiment of the present invention;

FIG. 2 is an enlarged illustration of the base of FIG. 1;

FIG. 3 is a simplified pictorial illustration of one of the solar panels of the array, constructed and operative in accordance with another embodiment of the present invention;

FIG. 4 is a simplified pictorial illustration of placing the solar panel on the base;

FIG. 5 is a simplified pictorial illustration of fixing the solar panel on the base;

FIG. 6 is a simplified pictorial illustration of the inside surface of the base;

FIG. 7 is an enlarged illustration of the inside surface of the base, showing electrical connections from the solar panel protruding out of the inside surface of the base;

FIG. 8 is a simplified pictorial illustration of the inside surface of the base, showing further electrical connections between all of the solar panels assembled on the base;

FIG. 9 is a simplified pictorial illustration of a protective cover for assembling over the solar panels that have been fixed on the base;

FIG. 10 is a simplified pictorial illustration of the protective cover after being assembled over the solar panels on the base;

FIG. 11 is a simplified side view illustration of the protective cover assembled over the solar panels on the base; and

FIG. 12 is a simplified pictorial illustration of the complete solar panel array assembled on a light fixture, in accordance with an embodiment of the present invention.

### DETAILED DESCRIPTION OF EMBODIMENTS

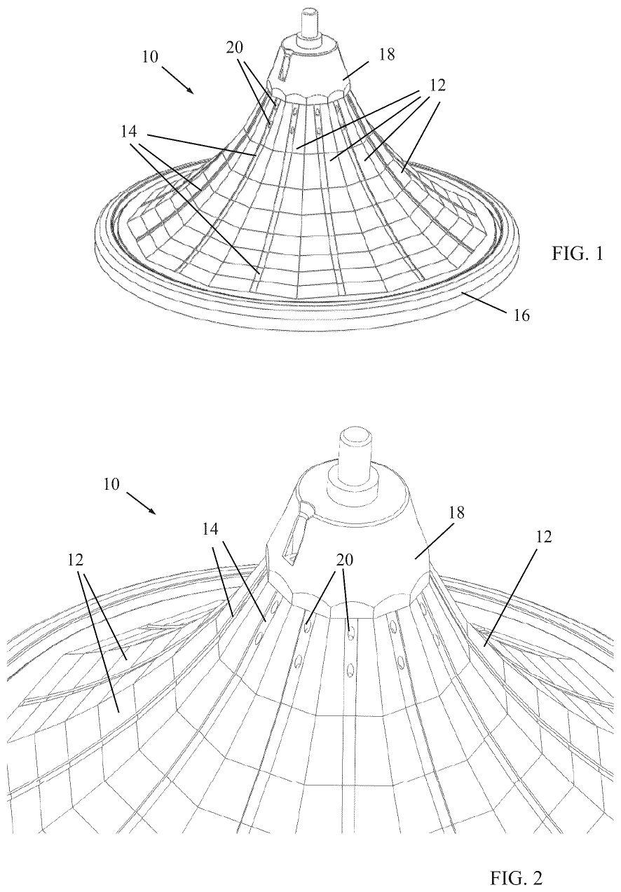

Reference is now made to FIGS. 1 and 2, which illustrate a base 10 for a solar panel array, constructed and operative in accordance with a non-limiting embodiment of the present invention.

Base 10 may have a curved outer contour, such as a concave cone shape (the illustrated embodiment, in which the sides of the cone curve inwards toward the vertical centerline of the cone, between the bottom and top of the cone), a convex cone shape (in which the sides of the cone curve outwards away from the vertical centerline of the cone, between the bottom and top of the cone) and others. Alternatively, base 10 may be a straight cone. Alternatively, base 10 may have a non-curved outer contour, such as a polyhedron and other shapes. The concave cone shape of the illustrated embodiment has the advantage of superior exposure to the sunlight for better solar energy output.

Base 10 includes a plurality of m sub-bases 12 around its periphery for mounting thereon solar panels. Each sub-base 12 may be formed with a trough 14 that extends at least partially (some or all of the way) from a lower portion or rim 16 of the base 10 to a top portion 18 of the base 10. The top portion 18 may include a cap and/or connector for connecting to some mechanical or electrical component of a light fixture, for example. Each sub-base 12 may also be formed with one or more apertures 20. The trough 14 may be used to receive therein a wire of the solar panel (as described below) and ends of the wire may be placed through the apertures 20 (as described below). The trough 14 and aperture 20 are also referred to as “cutouts”.

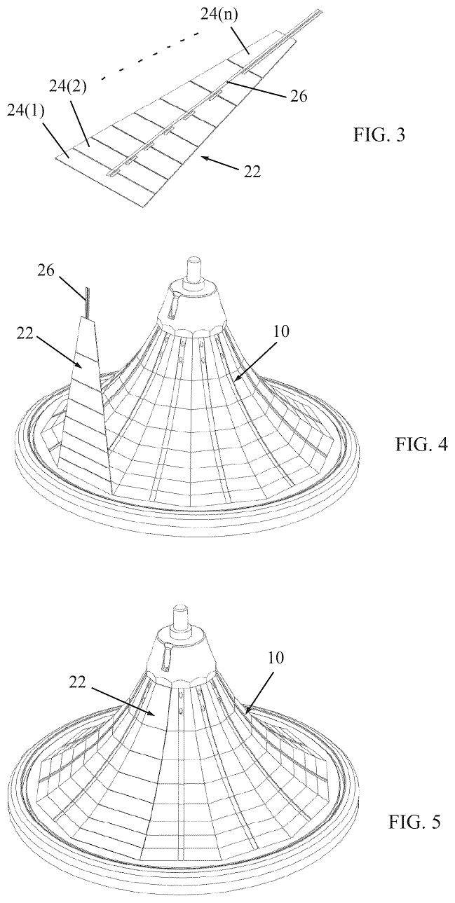

Reference is now made to FIG. 3, which illustrates a solar panel 22 of the array, constructed and operative in accordance with another embodiment of the present invention. Solar panel 22 is any kind of photovoltaic cell for generating electricity from solar energy, such as but not limited to, monocrystalline, polycrystalline or amorphous film cells.

In one-to-one correspondence with the m sub-bases 12 of base 10, there are m solar panels 22 mounted around the perimeter of base 10. Each solar panel 22 includes a plurality of n solar sub-panels 24(1) up to 24(n). The solar sub-panels 24 may be electrically connected to one another in parallel or series according to the battery charging requirement or other requirement. The solar sub-panels 24 may have unequal shapes, but the areas of all solar sub-panels 24 are equal. In other words, the area of solar sub-panel 24(1)=the area of solar sub-panel 24(2)=the area of solar sub-panel 24(3)= . . . =the area of solar sub-panel 24(n). For example, the length of the lowest solar sub-panel 24(1) is longer than the length of solar sub-panel 24(2), but the width of the lowest solar sub-panel 24(1) is less than the width of solar sub-panel 24(2) so that the areas are the same. The uppermost solar sub-panel 24(n) has the smallest length and largest width (length being the horizontal dimension and width being the vertical dimension).

As seen in FIG. 4, the trough 14 may be used to receive therein one or more electrical wires 26 (also seen in FIG. 3) of the solar panel 22. Wires 26 electrically connect the solar sub-panels 24. As seen in FIG. 7, ends of the wires 26 may be placed through the apertures 20. This construction provides several advantages. First, the wires 26 are held safely in place during assembly of the solar panels 22 on the base 10. Second, the wires 26 are fixed to the solar sub-panels 24 but are free to move with respect to the base 10. This simplifies assembly, including the steps of positioning the sub-panels and soldering or welding the electrical connections on the inner side of the base. Third, the trough 14 formed in sub-base 12 ensures that the wire 26 does not protrude above the outer surface and does not interfere with the solar panel 22 from lying on and fully touching the base 10. Fourth, the trough 14 enables using one single wire 26 for all the solar sub-panels 24.

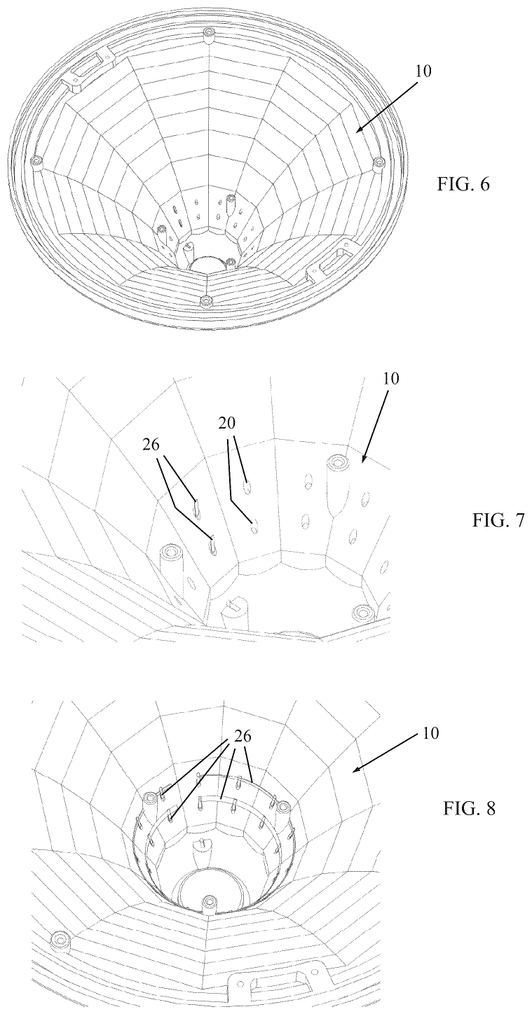

Reference is now made to FIGS. 4 and 5, in which the solar panel 22 is placed on the base 10 and bent to match the curve shape of the base 10. The solar panel 22 may be bonded to base 10 with adhesive or joined in any other suitable manner, such as with mechanical fasteners or welding and the like. FIG. 6 illustrates the inside surface of base 10. In FIG. 7, one can see the electrical connections (ends of wires 26) from the solar panel 22 protruding out of the inside surface of base 10. In FIG. 8, further electrical connections are made between all of the solar panels 22 assembled on base 10 with other wires 26.

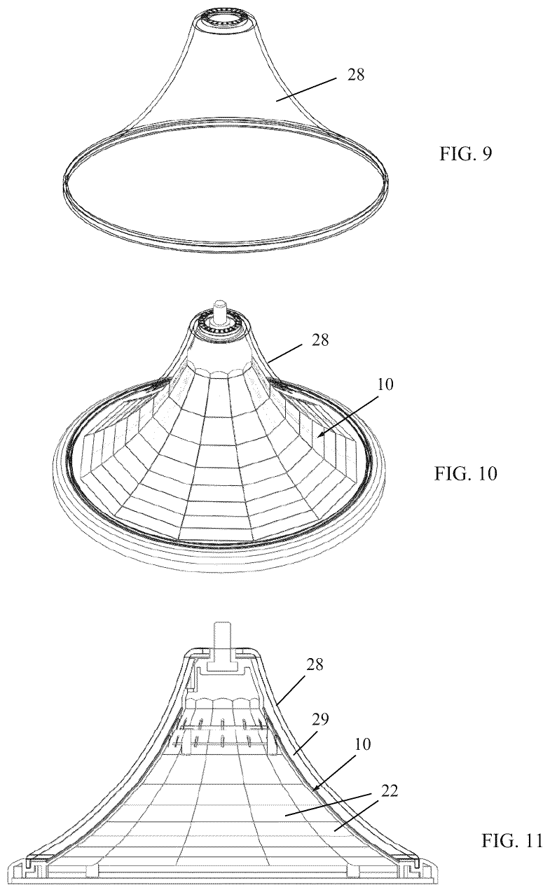

Reference is now made to FIG. 9, which illustrates a protective cover 28 for assembling over the solar panels 22 that have been fixed on base 10. Protective cover 28 may be constructed of a strong, transparent material with good resistance to ultraviolet radiation degradation, such as but not limited to, polycarbonate. FIGS. 10 and 11 illustrate the protective cover 28 after being assembled over the solar panels 22 on the base 10.

As seen in FIG. 11, the gap between the solar panels 22 and the inner periphery of protective cover 28 may be filled with a transparent filler material 29, such as but not limited to, a two-component polyurethane-based, epoxy-based or silicone-based material. The transparent filler material 29 may help fix panels 22 in place, to avoid breakage, chipping, or other damage. The transparent filler material 29 may also have good resistance to ultraviolet radiation degradation. The space and surfaces that come into contact with the material 29 as it is poured should be dust and grease free. All openings should be sealed to avoid leakage. During the crystallization of material 29 from liquid to solid, the assembly may remain in a thermal and vacuum chamber to avoid air bubbles and cracking.

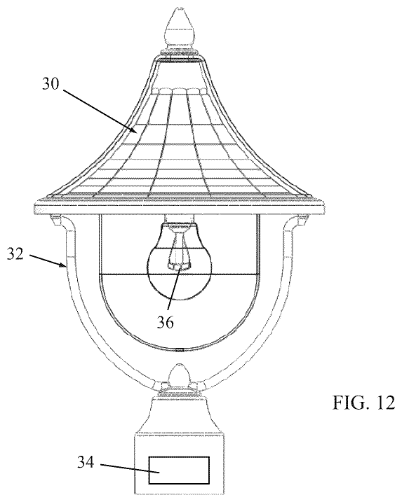

Reference is now made to FIG. 12, which illustrates the complete solar panel array 30 (solar panels 22 mounted on base 10 and covered by protective cover 28) assembled on a light fixture 32, in accordance with an embodiment of the present invention. The solar panel array 30 generates electricity from the sun to power the light fixture 32.

The solar panel array 30 may be mounted at the top of the light fixture 32 and generates electricity which is stored in one or more batteries 34, which are in electrical communication with solar panel array 30. The one or more batteries 34 power one or more lights 36 (such as, but not limited to, LED lights). The batteries 34 may be located at the bottom of the cap 18 (FIG. 1), or inside the pole or on the base of the pole or a portion of fixture 32 or at any other convenient location. The lights 36 may be located at any convenient location on the fixture. The light fixture 32 may be mounted on a pole, mounting bracket or other hardware.

What is claimed is:

1. A solar energy device comprising:
a solar panel array comprising solar panels, each of said solar panels having two non-parallel long sides both of which extend between a first side and a second side, said first side being shorter than said second side, and wherein each of said solar panels is divided into solar sub-panels, wherein said solar sub-panels have unequal shapes but equal areas;
wires electrically connecting said solar sub-panels and connecting said solar panels; and
a base on which said solar panels are secured, said solar panels being mounted around a vertical centerline of said base, and wherein said base and said solar panels are concave, curving radially inwards towards said vertical centerline.

2. The solar energy device according to claim 1, wherein said wires do not protrude above outer surfaces of said sub-bases and do not interfere with said solar panels from lying on and fully touching said base.

3. The solar energy device according to claim 1, wherein said base has a circular outer rim that extends radially outwards from said second sides of said solar panels.

4. The solar energy device according to claim 1, wherein base and said solar panels form a concave cone shape.

5. The solar energy device according to claim 1, wherein a top portion of said base comprises a cap or connector.

6. The solar energy device according to claim 1, further comprising a transparent protective cover assembled over said solar panels.

7. The solar energy device according to claim 6, wherein a gap between said solar panels and an inner periphery of said transparent protective cover is filled with a transparent filler material.

8. The solar energy device according to claim 1, further comprising a light fixture assembled with said solar panel array, said light fixture comprising one or more lights powered by energy generated by said solar panel array.

9. The solar energy device according to claim 1, wherein one of said wires connects all said solar sub-panels of a particular one of said solar panels.

10. The solar energy device according to claim 1, wherein said wires are fixed to said solar sub-panels but are free to move with respect to said base.

11. The solar energy device according to claim 1, wherein said semi-circular wire crosses over some of said wires that are placed through said apertures.
